(19) United States
(12) Patent Application Publication
(10) Pub. No.: US 2023/0128048 A1
(43) Pub. Date: Apr. 27, 2023

(54) CANISTER OF SEMICONDUCTOR PRODUCT DEVICE

(71) Applicant: DUKSAN TECHOPIA CO., LTD., Chungcheongnam-do (KR)

(72) Inventors: Sangwoong Yoon, Seoul (KR); Il Doo YANG, Sejong-si (KR); Hoe Sun JUNG, Sejong-si (KR); Young Chan KIM, Chungcheongnam-do (KR); Seung Bae PARK, Daegu (KR); Won Gyoung JUNG, Chungcheongbuk-do (KR); Ja Yeon KIM, Chungcheongnam-do (KR)

(21) Appl. No.: 17/666,775

(22) Filed: Feb. 8, 2022

(30) Foreign Application Priority Data
Oct. 25, 2021 (KR) 10-2021-0142539

(51) Int. Cl. C23C 16/448; C23C 16/455; H01L 21/768; H01L 21/67

(52) U.S. Cl. CPC C23C 16/4483; C23C 16/45548; H01L 21/76843; H01L 21/67017

(57) ABSTRACT

A canister for a semiconductor manufacturing device according to an embodiment of the present disclosure is provided with a sintered filter at the end of a dip tube into which a carrier gas is to be injected, and further provided with a porous container having excellent heat transfer rate inside a container, so that the precursor material filled inside the canister can be smoothly supplied to the thin film deposition device at a rear stage.

### CROSS-REFERENCE TO RELATED APPLICATION AND CLAIM OF PRIORITY

This application claims priority to Korean Patent Application No. 10-2021-0142539 filed on Oct. 25, 2021 in the Korean Intellectual Property Office (KIPO), the entire disclosures of which are incorporated by reference herein.

### BACKGROUND

### 1. Field

The present disclosure relates to a canister for a semiconductor manufacturing device, and more particularly, to a canister for a semiconductor manufacturing device that can improve the diffusion rate of carrier gas and improve heat transfer efficiency to precursor materials compared to the existing canister for semiconductor manufacturing device.

### 2. Description of the Related Art

In the manufacturing process related to electronic materials such as semiconductors and flat displays, when depositing a ceramic thin film and thick film such as a metal thin film, a metal nitride thin film or a metal oxide thin film, a process such as atomic layer deposition (ALD), chemical vapor deposition (CVD) or the like using precursors such as an organic metal compound, an inorganic metal compound or the like is used.

Precursors (chemical sources) used in processes such as ALD and CVD are filled in a separate canister specially manufactured for the purpose and supplied to the process, wherein the liquid phase or solid phase solid precursor material is vaporized in the canister and supplied into the reaction chamber of the vapor deposition device.

The canister for semiconductor manufacturing device includes a container filled with a precursor, a cover for covering the upper part of the container, a precursor material charging port provided in the cover, a carrier gas charging port provided on the cover, a supply tube connected to the carrier gas inlet port to supply the carrier gas into the container, and a discharge port through which the carrier gas discharged through the supply tube and the vaporized precursor material are discharged. The discharge port is provided on the cover and is connected to a thin film deposition device such as ALD and CVD.

Korean Unexamined Patent Publication Nos. 10-2012-0030658, 10-2014-0133469, etc. disclose canisters for semiconductor manufacturing processes, but there are problems that not only after liquid or solid precursors are vaporized inside the canister container, it is difficult to be discharged quickly together with the carrier gas, but also particulate impurities contained in the carrier gas are discharged, which may affect a subsequent vapor deposition process.

### SUMMARY

The present invention has been devised to solve the above-mentioned problems, and an object of the present invention is to provide a canister for a semiconductor manufacturing device including a dip tube provided with a sintered filter at the end thereof, so that the injected carrier gas spreads evenly throughout the inside of the canister while removing impurities contained in the carrier gas.

Another object of the present invention is to provide a canister having a porous container that can more efficiently vaporize a precursor material by smoothly performing the diffusion of a carrier gas and transferring heat to the precursor filled in the container.

In order to achieve one or more of the above objects, according to one aspect of the present disclosure, there is provided a canister for a semiconductor manufacturing device including: a container in which a precursor material used in a semiconductor thin film deposition process is to be stored and vaporized; a cover which is provided with a precursor material charging port into which the precursor material is to be charged and a carrier gas charging port into which the carrier gas is to be charged to seal the container; a porous container which is provided inside the container; a dip tube which is provided inside the porous container and transfers the carrier gas charged through the carrier gas charging port up to the bottom of the container; and a sintered filter which is mounted at the end of the dip tube to diffuse the carrier gas discharged from the dip tube into the inside of the container.

For example, the dip tube may be formed in a curved shape, and the dip tube may pass through the bottom surface of the porous container to be arranged on the bottom surface of the container.

According to an aspect of the present invention, the porous container may be formed of a metal capable of heat transfer, and the porous container has the same shape as the container.

In addition, the upper end of the porous container may be provided so as to be in close contact with the lower part of the cover.

According to an aspect of the present invention, there can be provided a canister in which a sintered filter is provided at the end of the dip tube to which the carrier gas is supplied, thereby capable of uniformly diffusing the injected carrier gas within the canister while minimizing impurities contained in the carrier gas.

In addition, according to an aspect of the present invention, there can be provided a canister in which the porous container is provided inside the main body container to smoothly performing the diffusion of the carrier gas, and the heat is transferred to the precursor filled in the container, thereby capable of vaporizing the precursor material more efficiently.

### BRIEF DESCRIPTION OF THE DRAWINGS

FIG. 1 is a plan view of a canister for a semiconductor manufacturing device according to an embodiment of the present invention; and

FIG. 2 is a cross-sectional view taken along the line A-A of FIG. 1.

### DETAILED DESCRIPTION OF THE EMBODIMENTS

Since the description of the present invention is merely an embodiment for structural or functional description, the scope of the present invention should not be construed as being limited by the embodiment described in the text.

In the description of the present invention, if it is determined that a specific description of the related known configuration or function may obscure the gist of the present invention, a detailed description thereof will be omitted.

In addition, it will be understood that when an element is referred to as being “on” or “above” another element, it can be “directly on” the other element or intervening elements may also be present.

Further, it will be understood that when an element is referred to as being “connected with” another element, the element can be directly connected with the other element or intervening elements may also be present. In contrast, it will be understood that when an element is referred to as being “directly connected with” another element, there are no intervening elements present.

As used herein, the singular forms “a,” “an” and “the” are intended to include the plural forms as well, unless the context clearly indicates otherwise. It will be further understood that the terms “comprise”, “include”, “have”, etc. when used in this specification, specify the presence of stated features, integers, steps, operations, elements, components, and/or combinations of them but do not preclude the presence or addition of one or more other features, integers, steps, operations, elements, components, and/or combinations thereof.

Unless otherwise defined, all terms used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Hereinbelow, embodiments of the present invention will be described in detail with reference to the accompanying drawings. In the description of the embodiments, the same elements will be given the same reference numerals.

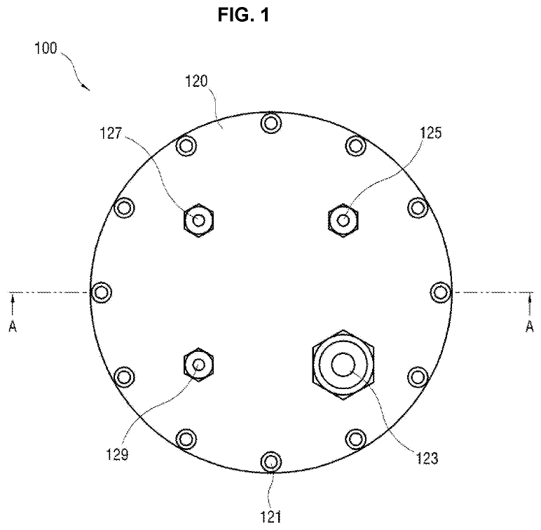

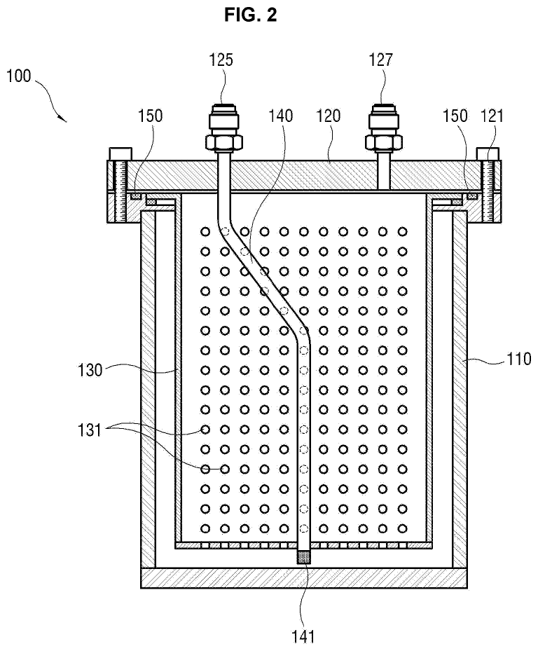

FIG. 1 is a plan view of a canister for a semiconductor manufacturing device according to an embodiment of the present invention, and FIG. 2 is a cross-sectional view taken along the line A-A of FIG. 1.

Referring to FIGS. 1 and 2, a canister 100 for a semiconductor manufacturing device according to an embodiment of the present invention includes a container 110 in which a precursor material used in a semiconductor thin film deposition process is stored and vaporized, a cover 120 which seals the container, a porous container 130 which is provided inside the canister container 110, a dip tube 140 to which a carrier gas is supplied, and the like.

The cover 120 and the container 110 may be closely connected by a fastening means 121 such as a screw or pin-shaped fastener and a gasket 150, or the like. That is, a gasket 150 is mounted between the container 110 and the cover 120, and the container 110 and the cover 120 are fastened using the fastening means 121. By closely connecting the cover 120 and the container 110 in this way, it is possible to prevent oxygen, moisture, contaminants, and the like existing in the exterior from flowing into the canister.

A porous container 130 is provided inside the canister container 110. The porous container 130 preferably has the same shape as the canister container 110 (external container).

Further, the canister container 110 is preferably installed to be spaced apart from the external container 110, which is for allowing the carrier gas discharged through the dip tube 140 to smoothly enter and exit to the interior of the porous container 130.

The porous container 130 is preferably formed of a metal having excellent thermal conductivity, and a plurality of holes 131 through which the carrier gas can enter and exit are formed on the entire surface, such as the side surface part and the bottom surface part. At this time, the size and number of the holes 131 can be appropriately selected.

The porous container 130 is installed inside the canister container 110, whereby there is advantages in that not only it is possible to smoothly perform the diffusion of a carrier gas such as nitrogen, argon, etc., and to sufficiently uniformly transfer heat to the filled precursor material, thereby promoting vaporization, but also the precursor material vaporized according to the smooth diffusion of the carrier gas can be smoothly discharged to a discharge port 127.

The cover 120 may be provided with a precursor material charging port 123, a carrier gas charging port 125, a discharge port 127, and the like, and an emergency exhaust port 129 can be further provided. The emergency exhaust port 129 is provided to control the internal pressure of the canister 100 when an abnormal phenomenon such as clogging in the discharge port 127 occurs.

A liquid or solid precursor material may be charged into the canister via the precursor material charging port 123. The precursor charged via the precursor material charging port 123 is vaporized inside the canister and discharged to the discharge port 127. The canister is appropriately heated so that the precursor material filled inside the container 110 is vaporized.

The carrier gas charging port 125 is connected to a dip tube 140. Therefore, an inert gas such as nitrogen or argon injected via the carrier gas charging port 125 passes through the dip tube 140 and is charged into the canister. The tip tube 140 is preferably formed long in the vertical direction so that the carrier gas can be injected up to the bottom surface of the canister container 110.

One end of the dip tube 140 is connected to the carrier gas charging port 125, and the other end of the dip tube 140 is located inside the container 110. At this time, it is preferable that the dip tube 140 is formed longer to the extent that the end part (the part where the carrier gas is discharged) is closer to the bottom surface of the canister container 110. For example, the end part of the sintered filter mounted on the dip tube 140 may be formed long so as to be spaced apart from the bottom surface of the container 110 by 3 to 10 mm, preferably by about 5 mm. When the end of the dip tube 140 is formed long so as to be close to the bottom surface of the container 110 in this way, the injected carrier gas collides with the bottom surface and then can be sufficiently diffused to the peripheral part by the counteraction.

The other end of the dip tube 140 is preferably provided so as to be located through the porous container 130. That is, the other end of the dip tube 140 is preferably located between the lower bottom surface of the porous container 130 and the upper bottom surface of the canister container 110.

Further, the dip tube 140 is preferably formed in a curved shape. This is for efficiently diffusing the carrier gas, and as described above, the cover 120 must be provided with a carrier gas charging port 125, a precursor material charging port 123, a discharge port 127, an emergency discharge port 129 and the like in addition to the carrier gas charging port 125, whereby the carrier gas charging port 125 cannot be formed in the center of the cover 120. Therefore, the dip tube 140 connected to the carrier gas charging port 125 is configured so as to be located at the center of the container 110, and should be in a curbed shape in order to increase the diffusion efficiency of the carrier gas.

A sintered filter 141 is mounted to the end of the dip tube 140 from which the carrier gas is discharged. By providing the sintered filter 141, particulate impurities contained in the carrier gas can be removed, and the directionality of the carrier gas discharged from the dip tube 140 can be offset so that the carrier gas diffuses throughout the inside of the canister.

The carrier gas that has passed through the sintered filter 141 is diffused throughout the inside of the container 110, and in the process in which the carrier gas flows into the interior of the porous container 130 through the hole of the porous container 130, turbulence is formed, the precursor material charged in the canister 100 can be uniformly consumed due to such turbulence, so that the precursor material can be smoothly discharged via the discharge port 127.

That is, a carrier gas is used to smoothly discharge the vaporized precursor to the discharge port 127. At this time, an inert gas such as nitrogen or argon is preferably used as the carrier gas so as not to cause a reaction with the precursor.

The carrier gas and the vaporized precursor material are supplied to a thin film deposition equipment (not shown) such as ALD and CVD at a rear stage through the discharge port 127 provided in the cover 120. That is, the discharge port 127 is connected to a thin film deposition equipment such as ALD or CVD.

At this time, a heating jacket (not shown) is installed on all lines from the canister and the discharge port 127 to the process chamber of the thin film deposition equipment such as ALD or CVD. By installing the heating jacket, it is possible to prevent recondensation of the precursor that is vaporized and injected. The temperature of the heating jacket can vary from room temperature to about 150° C. depending on the thermal properties of the solid or liquid precursor material.

In addition, by providing a filter (not shown) in the discharge port 127, it is possible to prevent liquid or solid precursor materials other than vaporized gas from flowing into the thin film deposition equipment at a rear stage.

Therefore, according to the present invention, there is an advantage in that a sintered filter 141 is provided at the end of the dip tube 140, and a porous container 130 having an excellent heat transfer rate is further provided inside the canister container 110, so that the precursor material filled inside the canister can be smoothly supplied to the thin film deposition equipment at the rear stage.

Although exemplary embodiments of the present disclosure have been described for illustrative purposes, those skilled in the art will appreciate that various modifications, additions and substitutions are possible, without departing from the scope and spirit of the disclosure. Therefore, exemplary embodiments of the present disclosure have not been described for limiting purposes. Accordingly, the scope of the disclosure is not to be limited by the above embodiments but should be construed by the following claims, and all techniques within a range equivalent thereto should be construed as being included within the spirit and scope of the present invention.

What is claimed is:

1. A canister for a semiconductor manufacturing device, comprising:
a container in which a precursor used in a semiconductor thin film deposition process is to be stored and vaporized;
a cover configured to seal the container, the cover provided with a precursor charging port into which the precursor is to be charged and a carrier gas charging port into which a carrier gas is to be charged;
a porous container provided inside the container;
a dip tube provided inside the porous container, the dip tube configured to transfer the carrier gas charged through the carrier gas charging port to a bottom of the container; and
a sintered filter mounted at the end of the dip tube to diffuse the carrier gas discharged from the dip tube into an inside of the container.

2. The canister of claim 1, wherein the dip tube has a curved shape.

3. The canister of claim 1, wherein the dip tube is configured to pass through a bottom surface of the porous container to be arranged on a bottom surface of the container.

4. The canister of claim 1, wherein the porous container is formed of a metal.

5. The canister of claim 1, wherein the porous container has the same shape as the container.

6. The canister of claim 1, wherein an upper end of the porous container is to be in close contact with a lower part of the cover.
